(19) United States
(12) Patent Application Publication
(10) Pub. No.: US 2026/0026381 A1
(43) Pub. Date: Jan. 22, 2026

(54) SEMICONDUCTOR DEVICE WITH A TWO-SIDED REDISTRIBUTION LAYER

(71) Applicant: Micron Technology, Inc., Boise, ID (US)

(72) Inventor: Yeon Seung Jung, Hwaseong (KR)

(21) Appl. No.: 19/271,642

(22) Filed: Jul. 16, 2025

Related U.S. Application Data
(60) Provisional application No. 63/673,666, filed on Jul. 19, 2024.

(51) Int. Cl. H01L 23/538; H01L 21/48; H01L 21/768; H01L 23/00; H01L 23/367; H01L 25/18; H10B 80/00; H10D 80/30

(52) U.S. Cl. CPC H01L 23/5386; H01L 21/4875; H01L 21/76898; H01L 23/3675; H01L 24/14; H01L 24/16; H01L 25/18; H10B 80/00; H10D 80/30; H01L 23/5385; H01L 24/08; H01L 24/80; H01L 2224/08225; H01L 2224/1403; H01L 2224/14183; H01L 2224/16225; H01L 2224/80895; H01L 2224/80896; H01L 2924/14361

(57) ABSTRACT

A semiconductor device with a two-sided redistribution layer is disclosed. The semiconductor device comprises a host device and one or more memory stack cubes. A redistribution layer is disposed between and couples the host device and the memory stack cubes. This redistribution layer features an edge surface extending between the host device and the memory stack cubes. The semiconductor device includes first connective circuitry that extends through the redistribution layer, is coupled with the host device, and is exposed at the edge surface of the redistribution layer. Additionally, second connective circuitry extends through the redistribution layer, is coupled with the memory stack cubes, and is exposed at the edge surface of the redistribution layer. Connective structures couple the first and second connective circuitry exposed at the edge surface of the redistribution layer.

### CROSS-REFERENCE TO RELATED APPLICATION(S)

The present application claims priority to U.S. Provisional Patent Application No. 63/673,666, filed Jul. 19, 2024, the disclosure of which is incorporated herein by reference in its entirety.

### TECHNICAL FIELD

The present disclosure generally relates to semiconductor device assemblies and more particularly relates to a semiconductor device with a two-sided redistribution layer.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly in accordance with an embodiment of the present technology.

FIG. 2 illustrates a simplified schematic partial plan view of a semiconductor device assembly in accordance with an embodiment of the present technology.

FIGS. 3-7 illustrate simplified schematic partial plan and cross-sectional views of a series of operations for fabricating semiconductor device assemblies in accordance with embodiments of the present technology.

FIG. 8 illustrates a schematic view of a system that includes a semiconductor device assembly configured in accordance with an embodiment of the present technology.

FIG. 9 illustrates a method of fabricating a semiconductor device assembly in accordance with an embodiment of the present technology.

### DETAILED DESCRIPTION

Multiple semiconductor dies can be packaged into a single semiconductor device that can operate cooperatively and provide a particular functionality; however, these designs can also introduce various challenges. For example, semiconductor devices can be at risk of overheating due to an increased amount of heat generated by multiple dies within a single package. These dense package structures can require complex routing, thus dictating that semiconductor dies be located at positions that prioritize connectivity over thermal advantages. For example, semiconductor dies that include dense circuitry or require large amounts of external connections (e.g., power, ground, input/output (I/O)) to operate are positioned at the bottom of the package closest to an interposer but furthest from thermal regulation elements (e.g., heat spreaders, heat sinks, or lids) used to dissipate heat. Often, however, these same semiconductor dies (e.g., logic dies) produce the largest amount of heat due to their dense circuitry or the large power distributions required to operate these dies. Thus, semiconductor devices can benefit from alternate thermal regulation techniques, particularly those that enable thermal regulation elements to be proximate to the semiconductor dies that produce the greatest amount of heat (e.g., logic dies).

Take, for example, a system-in-package (SiP) device in which one or more high-bandwidth memory (HBM) cubes (sometimes also referred to herein as “HBM devices”) are connected to a host device. In a typical SiP configuration, HBM devices may be integrated with a host device (e.g., a graphics processing unit (GPU), a central processing unit (CPU), a tensor processing unit (TPU), and/or any other suitable processing unit) using a base substrate (e.g., a silicon interposer, a substrate of organic material, a substrate of inorganic material, and/or any other suitable material that provides interconnection between the host device and the HBM device and/or provides mechanical support for the components of a SiP device), through which the HBM devices and the host device communicate. Because traffic between the HBM devices and the host device resides within the SiP (e.g., using signals routed through the interposer), a higher bandwidth may be achieved between the HBM devices and the host device than in conventional systems. In other words, the through-substrate vias (TSVs) interconnecting memory dies within an HBM device and route lines in the interposer (sometimes referred to collectively as part of a system bus) enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., GPU/CPU) and HBM devices during operation. For example, the high-bandwidth channels can be on the order of 1,000 gigabytes per second (GB/s, sometimes also referred to as gigabits (Gb)). It will be appreciated that such high-bandwidth data transfer between a host device and memory dies of HBM devices can be advantageous in various high-performance computing applications, such as video rendering, high-resolution graphics applications, artificial intelligence and/or machine learning (AI/ML) computing systems and other complex computational systems, and/or various other computing applications.

These designs can also be suboptimal for thermal regulation or communication efficiency. For example, in one design, the HBM cubes and the host device can be coupled to a same side of an interposer through which the host device and the HBM cubes communicate. The HBM cubes can be arranged around the host device. A thermal dissipater or lid can then be placed over the HBM cubes and the host device to remove heat from the package. Given that the host device and the HBM cubes are coupled to the same surface and their heights may differ, however, the thermal dissipater may be spaced from either the HBM cubes or the host device, thereby limiting heat dissipation from the package.

In contrast to this design, the present technology includes a SiP device in which the HBM cubes and the host device are implemented on opposite sides of an interposer. Connective circuitry exposed at an edge surface of the interposer that extends between the opposite sides is disposed through the interposer and couples to the HBM cubes and the host device. The portions of the connective circuitry exposed at the edge surface thus provide external connectivity to the host device and the HBM cubes through the interposer. Connective structures (e.g., solder bumps, solder balls, conductive pillars, or other conductive elements) can be disposed at the exposed portions of the connective circuitry and used to couple the SiP device to a substrate (e.g., a motherboard). In this way, the SiP device can be laid down on the substrate and horizontally coupled with the interposer instead of having the interposer vertically stacked thereon.

By implementing the host device and the HBM cubes in a laid-down configuration on opposite sides of the interposer, thermal regulation elements such as a heat spreader, heat sink, or lid can be placed in close proximity to the host device and the HBM cubes without these devices needing to have a same or similar thickness. Instead, the thermal regulation element can be designed to at least partially surround both the host device and the HBM cubes. In this way, thermal regulation of the SiP can be improved. Moreover, because the HBM cubes and the host device are implemented on opposite sides of the interposer, the host device and the HBM cubes can be connected through connective circuitry that extends between the opposite sides of the interposer. This connective circuitry can be shorter than connective circuitry that couples the host device and the HBM cubes when the host device and the HBM cubes are laterally spaced across the interposer. For example, the connective circuitry coupling the host device and HBM cubes on opposite sides of the interposer can be between 50 and 100 micrometers, while connective circuitry coupling the host device and HBM cubes in a laterally spaced arrangement can be around 6 millimeters in length. As a result of these shorter interconnects, noise and latency can be reduced.

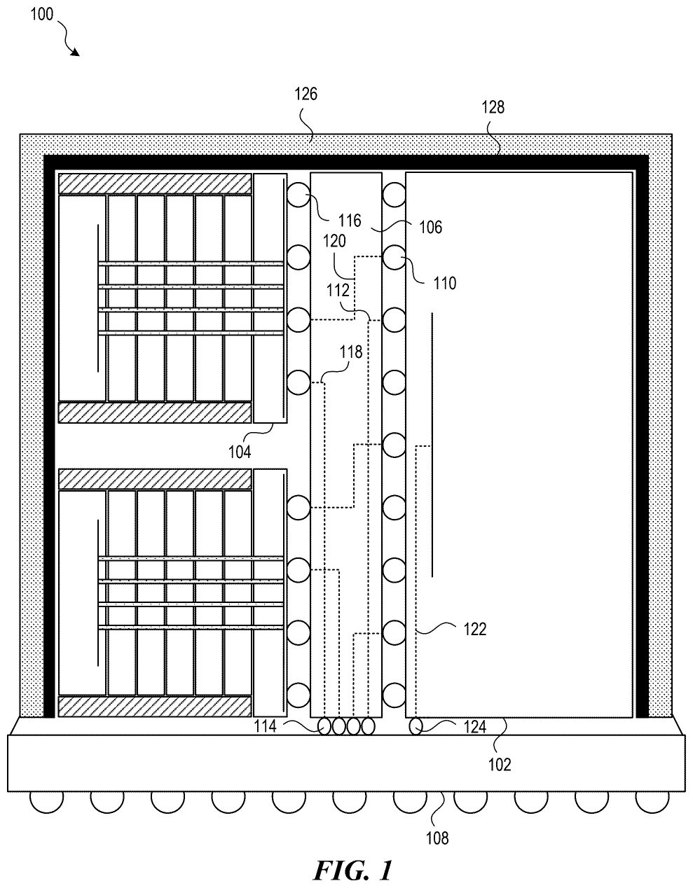

FIG. 1 illustrates a semiconductor device assembly 100 that includes a host device 102 and one or more HBM cubes 104 coupled (e.g., electrically and mechanically) at opposite sides of an interposer 106. The semiconductor device assembly 100 can be arranged as a SiP device. As shown, the semiconductor device assembly 100 can be carried by a package substrate 108 (e.g., a silicon substrate, an organic substrate, an inorganic substrate, a PCB, or any other suitable base substrate). The host device 102 can be coupled with the interposer 106 (e.g., or any other suitable base substrate implementing a redistribution layer) at a first side, and the HBM cubes 104 can be coupled with the interposer 106 at a second side opposite the first side. In aspects, the host device 102 and the HBM cubes 104 can be coupled such that faces of the host device 102 and the HBM cubes 104 face the interposer 106 (e.g., and one another). In this way, interconnects between the host device 102 and the HBM cubes 104 can be shortened to reduce communication noise and latency.

The host device 102 (e.g., a GPU, CPU, TPU, and/or any other suitable processing unit) can include, among other features, a register and one or more levels of cache (e.g., an L1 cache, an L2 cache, and/or the like). The host device 102 can communicate with the HBM cubes 104 or any other components (e.g., connected through the substrate 108) through the interposer 106. For example, connective structures 110 (e.g., solder balls, conductive pillars, or other conductive structures) can be disposed at contact pads (not shown) at the host device 102 (e.g., coupled with system-on-chip (SoC) pins of the host device 102) and used to couple the host device 102 with the interposer 106 at connective circuitry 112 (e.g., traces, lines, vias, contact pads, and other routing circuitry) exposed at the first side of the interposer 106. The connective circuitry 112 can be disposed throughout the interposer 106 (e.g., in a routing layer formed from dielectric and conductive material) and exposed at an edge surface of the interposer 106 to provide external connectivity to the host device 102 through the interposer 106. For example, connective structures 114 (e.g., solder bumps, solder balls, conductive pillars, and so on) can be disposed at the connective circuitry 112 exposed at the edge surface of the interposer 106 to couple the interposer 106 with the substrate 108 and provide external connectivity (e.g., power, ground, I/O signaling, etc.) through the substrate 108. In aspects, the connective circuitry 112 can implement at least a portion of a Peripheral Component Interconnect Express (PCIe) bus.

The HBM cubes 104 can similarly couple with the interposer 106 at the second side of the interposer 106 through connective structures 116. The connective structures 116 can couple contact pads (not shown) exposed at the HBM cubes 104 (e.g., direct access (DA) ports of the HBM cubes 104) with connective circuitry 118 exposed at the second side of the interposer 106 (e.g., in a routing layer formed from dielectric and conductive material). The connective circuitry 118, like the connective circuitry 112, can extend through the interposer 106 and be exposed at the edge surface of the interposer 106, where connective structures 114 are disposed to provide external connectivity to the HBM cubes 104 through the substrate 108.

In aspects, the connective circuitry 112 or the connective circuitry 118 exposed at the edge surface of the interposer 106 does not include contact pads that provide a surface with which to couple the connective structures 114. Instead, traces or route lines of the connective circuitry 112 or the connective circuitry 118 can be exposed at the edge surface of the interposer 106 (e.g., through sawing or grinding), and contact by the connective structures 114 can be made therewith. In other cases, the connective circuitry 112 or the connective circuitry 118 can include contact pads at which the connective structures 114 couple.

Each of the HBM cubes 104 can include an interface die, one or more memory dies carried by the interface die, and one or more TSVs coupled to the interface die and each of the memory dies. The TSVs allow each of the dies in the HBM cubes 104 to communicate data (e.g., between the memory dies) and the interface die (sometimes also referred to herein as a “base die,” a “logic die,” and/or the like) at a relatively high rate (e.g., on the order of 1,000 GB/s or greater). The memory dies of the HBM cubes 104 can have a smaller footprint than the interface die. Thus, the memory dies can be at least partially surrounded by an encapsulant (e.g., a mold resin, dielectric fill, or the like).

The HBM cubes 104 (e.g., through the interface die) can communicate the data to the host device 102, and vice versa. For example, connective circuitry 120 formed in the interposer 106 can couple to the host device 102 at the first side (e.g., through connective structures 110) and to the HBM cubes 104 at the second side (e.g., through connective structures 116). In this way, the host device 102 can be coupled directly to the HBM cubes 104 exclusive of the substrate 108. The connective circuitry 120 can be used to communicate signaling directly between the host device 102 and the HBM cubes 104 (e.g., to read, write, and perform other operations at the HBM cubes 104). In aspects, the connective circuitry 120 can couple with a host physical layer (PHY) at the host device 102 and the HBM PHYs at the HBM cubes 104. The connective circuitry 120 can include traces, lines, vias, TSVs, contact pads, or any other routing circuitry that can be used to connect circuit components. In aspects, the connective circuitry 120 includes TSVs extending through the interposer 106. In aspects, the connective circuitry 120 can be shorter (e.g., between 50 and 100 micrometers) than connective circuitry used to connect a host device to laterally spaced HBM cubes arranged on a same side of an interposer (e.g., around 6 millimeters). As a result, noise and latency between the host device 102 and the HBM cubes 104 can be reduced.

Although discussed as including a separate interposer 106, the interposer could instead be replaced with a redistribution layer implemented directly on the host device 102 or the HBM cubes 104. For example, layers of dielectric material and conductive material can be disposed at the host device 102 to implement the connective circuitry 112, the connective circuitry 118, and the connective circuitry 120. The HBM cubes 104 can then be directly attached to the host device 102 through the redistribution layer. In this way, the size of the SiP and the size of interconnects between the host device 102 and the HBM cubes 104 can be reduced, thereby increasing design flexibility and reducing communication noise and latency.

In some implementations, the host device 102 can include additional connective circuitry 122 coupled with functional circuitry at the host device 102 and exposed at an edge surface of the host device 102 to provide connectivity to the substrate 108 through connective structures 124 (e.g., solder bumps, solder balls, conductive pillars, and so on). The edge surface of the host device 102 can be substantially coplanar (e.g., within 1, 2, 5, 10, or 15 degrees of coplanar) with the edge surface of the interposer 106 or substantially orthogonal (e.g., within 1, 2, 5, 10, or 15 degrees of orthogonal) with and extending from the surface at which the host device 102 is coupled with the interposer 106. The additional connective circuitry 122 can be disposed in a routing layer of the host device 102 (e.g., or a redistribution layer formed on the host device 102) formed from dielectric and conductive material. Like the connective structures 114 with the connective circuitry 112 and the connective circuitry 118, the connective structures 124 can couple directly with exposed traces or route lines of the connective circuitry 122 exposed at the edge surface of the host device 102. In this way, contact pads may not be required at the edge surface of the host device 102. Through the connective circuitry 122, the substrate 108 can provide external connectivity to the host device 102 exclusive of the interposer 106. In addition to providing direct access to the host device 102, the connective circuitry 122 can increase the area at which connections between the host device 102 and the substrate 108 can be made (e.g., both inclusive and exclusive of the interposer 106).

In some cases, the host device 102, the HBM cubes 104, and the interposer 106 can be encapsulated, for example, using a mold resin. A thermally conductive lid 126 can be disposed at least partially over the host device 102, the HBM cubes 104, and the interposer 106. For example, the thermally conductive lid 126 can be disposed over the tops of the host device 102 and the HBM cubes 104 (e.g., located furthest from the interposer 106) or over one or more edge surfaces of the host device 102, the HBM cubes 104, or the interposer 106. As illustrated, the thermally conductive lid 126 extends across side surfaces of the host device 102, one or more of the HBM cubes 104, and the interposer 106 and down top surfaces of the host device 102 and the HBM cubes 104. The thermally conductive lid 126 can be disposed directly on a surface of the host device 102, the HBM cubes 104, or the interposer 106 or proximate (e.g., within 1, 2, 5, 10, 100, or 500 microns) but spaced from the host device 102, the HBM cubes 104, or the interposer 106 (e.g., by an encapsulant or other material). In general, however, the thermally conductive lid 126 can be thermally coupled with the host device 102 and the HBM cubes 104 to remove heat from the host device 102 or the HBM cubes 104 through the thermally conductive lid 126. In aspects, the thermally conductive lid 126 can include any thermally conductive material such as aluminum, tin, copper, gold, or any other material having beneficial thermal properties (e.g., high thermal conductivity).

Given that the host device 102 and the HBM cubes 104 are disposed on opposite sides of the interposer 106, the host device 102 and the HBM cubes 104 need not be the same height (or close to the same height) to provide thermal dissipation to both the host device 102 and the HBM cubes 104 using the thermally conductive lid 126. Instead, the thermally conductive lid 126 can be formed to provide thermal dissipation through the side surfaces or top surfaces of the host device 102 and the HBM cubes 104 regardless of their relative size. Thus, the semiconductor device assembly 100 can have improved thermal regulation while accommodating various designs.

A thermal interface material (TIM) 128 can be disposed between the thermally conductive lid 126 and the host device 102, the HBM cubes 104, and the interposer 106 to facilitate heat transfer between the components. For example, the TIM 128 can be disposed over the tops of the host device 102 and the HBM cubes 104 (e.g., located furthest from the interposer 106) or over one or more edge surfaces of the host device 102, the HBM cubes 104, or the interposer 106. The TIM 128 can be disposed directly on a surface of the host device 102, the HBM cubes 104, or the interposer 106 or proximate (e.g., within 1, 2, 5, 10, or 100 microns) but spaced from the host device 102, the HBM cubes 104, or the interposer 106 (e.g., by an encapsulant or other material). In general, the TIM 128 can be a thermal paste or grease, a thermal pad, phase change materials, or thermal adhesives. The TIM 128 can include a thermally conductive material. For example, the TIM 128 can include aluminum oxide, zinc oxide, boron nitride, polymers filled with thermally conductive material (e.g., ceramic powders or metal particles), or adhesives (e.g., epoxies) filled with thermally conductive materials (e.g., silver, aluminum, or ceramic).

Although described above in the context of HBM cubes, the HBM cubes 104 can be replaced with different memory devices. For example, the HBM cubes can be replaced with any volatile storage elements, such as dynamic random-access memory (DRAM) storage elements. Memory dies configured in accordance with other embodiments of the present technology, however, can include other types of storage elements (e.g., in addition to or in lieu of DRAM storage elements), such as other types of volatile storage elements (e.g., static random-access memory (SRAM) storage elements) and/or non-volatile storage elements (e.g., NOT-AND (NAND), NOT-OR (NOR), phase change memory (PCM), ferroelectric random-access memory (FeRAM), resistive random-access memory (RRAM), and magnetic random-access memory (MRAM), among others). Additionally, or alternatively, semiconductor device assemblies configured in accordance with other embodiments of the present technology can incorporate other types of memory devices (e.g., hybrid memory cubes) in addition to or in lieu of the HBM cubes 104.

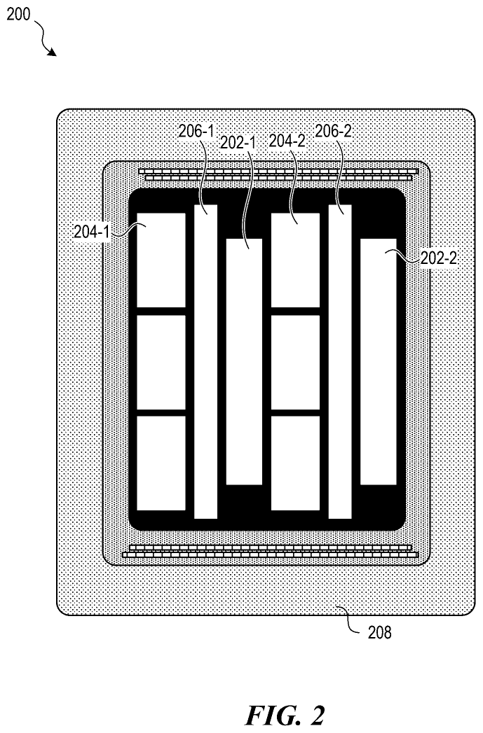

FIG. 2 illustrates a simplified schematic partial plan view of a semiconductor device assembly 200 in accordance with an embodiment of the present technology. The plan view can illustrate a top-down view of a semiconductor device that includes multiple host devices 202 (e.g., host device 202-1 and host device 202-2) and sets of HBM cubes 204 (e.g., HBM cubes 204-1 and HBM cubes 204-2) coupled through respective interposers 206 (e.g., interposer 206-1 and interposer 206-2). For example, the host devices 202 and the sets of HBM cubes 204 can be coupled to respective ones of the interposers 206 as described with respect to FIG. 1. The interposers 206 can then be coupled to a substrate 208 at different lateral locations.

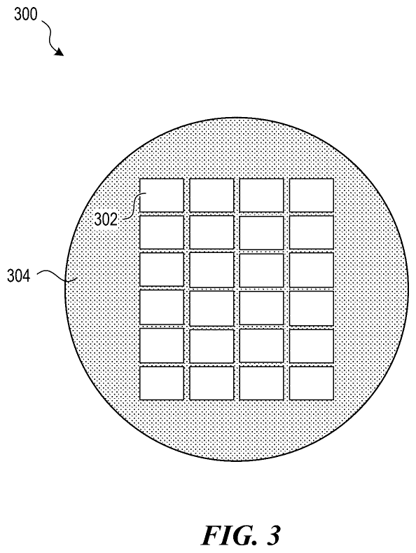

This disclosure now turns to a series of operations for fabricating semiconductor device assemblies in accordance with embodiments of the present technology. Specifically, FIGS. 3-7 illustrate simplified schematic cross-sectional views of a series of operations for fabricating semiconductor device assemblies in accordance with an embodiment of the present technology. The operations are illustrated with respect to a specific embodiment for ease of description. However, the operations described with respect to FIGS. 3-7 could be performed to fabricate semiconductor device assemblies in accordance with other embodiments. Operations described herein are discussed as wafer-level operations for example only. In general, however, the operations disclosed herein can be performed at the die level for a single semiconductor device assembly or at the wafer or panel level for multiple semiconductor device assemblies.

FIG. 3 illustrates a simplified schematic partial plan view of a semiconductor device assembly at stage 300, where HBM cubes 302 are assembled onto a wafer 304. In implementations that utilize a discrete interposer between the host device and respective sets of the HBM cubes 302, the wafer 304 can include interposers on which sets of the HBM cubes 302 are assembled (e.g., the number of HBM cubes in each SiP are assembled onto an interposer). For example, the HBM cubes 302 can be attached to the wafer 304 such that faces of the HBM cubes 302 are coupled with the wafer 304. The HBM cubes 302 can be coupled electrically and mechanically with respective interposers through any appropriate technique (e.g., hybrid bonding, solder balls, conductive pillars, or any other connective structure). The interposers can include a routing layer (e.g., formed from dielectric and conductive material) at which connective circuitry is exposed. The HBM cubes 302 can then be attached to the interposers at the routing layer through the exposed circuitry.

In cases where the interposer is replaced with a redistribution layer formed on the HBM cubes 302 or the interposer is attached to a reconstructed wafer of the HBM cubes 302, the wafer 304 can comprise a carrier wafer on which the HBM cubes 302 are adhered. For example, the HBM cubes 302 can be assembled onto the wafer 304 such that the backs of the HBM cubes 302 are attached to the wafer 304 and the faces of the HBM cubes 302 are exposed. The carrier wafer can support the HBM cubes 302 during the assembly process. Once the HBM cubes 302 are attached to the wafer 304, a reconstructed wafer can be formed by filling the gaps between the HBM cubes 302 (e.g., with a mold resin or oxide fill). Additional operations can then be performed on the reconstructed wafer, as illustrated in the following figures.

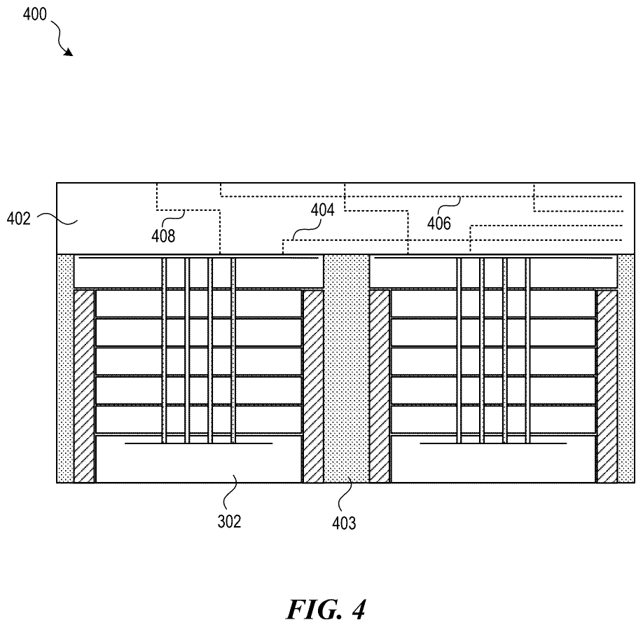

FIG. 4 illustrates a simplified schematic cross-sectional view of a semiconductor device assembly at stage 400, where a redistribution layer 402 is formed or coupled with the HBM cubes 302 in a reconstructed wafer. The reconstructed wafer can be formed by filling the space between the HBM cubes 302 with a gap fill 403 (e.g., oxide fill or mold resin). In aspects, the semiconductor device assembly illustrated in FIG. 4 corresponds to a set of HBM cubes 302 to be coupled with a single interposer or redistribution layer, however, the steps described herein can be performed across each set of HBM cubes disposed on the wafer. Moreover, the following figures are illustrated in accordance with embodiments in which the redistribution layer 402 is formed directly onto the HBM cubes 302. However, the redistribution layer 402 can instead be implemented as a discrete interposer coupled with the HBM cubes 302 (e.g., through connective structures).

The redistribution layer 402 can be formed of layers of dielectric material with selectively deposited conductive material to form connective circuitry. For example, the redistribution layer 402 can include connective circuitry 404 coupling with the HBM cubes 302 and extending toward the periphery of the set of HBM cubes 302. In this way, the connective circuitry 404 can provide external connectivity to the HBM cubes 302 once exposed (e.g., through singulation or grinding) at an edge of the redistribution layer 402. The redistribution layer 402 can further include connective circuitry 406 exposed at a side opposite the side at which the HBM cubes 302 couple with the redistribution layer 402 and extending toward the periphery of the set of HBM cubes 302. The connective circuitry 404 can thus provide external connectivity to any components coupled with the connective circuitry 404 (e.g., a host device) once exposed (e.g., through singulation or grinding) at an edge of the redistribution layer 402.

The redistribution layer 402 includes connective circuitry 408 extending between the sides of the redistribution layer 402. For example, the HBM cubes 302 can be coupled with the connective circuitry 408 at a first side of the redistribution layer 402, and the connective circuitry 408 can be exposed at the opposite side of the redistribution layer 402. Thus, once an additional component (e.g., the host device) is coupled with the redistribution layer 402 opposite the HBM cubes 302, the connective circuitry 408 can communicate signaling between the HBM cubes 302 and these additional components.

In embodiments in which an interposer is used to implement the redistribution layer 402, the connective circuitry 404 can be formed before attaching and coupling the HBM cubes 302 thereto. Similarly, a portion of the connective circuitry 408 located at the side on which the HBM cubes 302 are attached can be formed before attaching and coupling the HBM cubes 302 thereto. Then, once the HBM cubes 302 are coupled with this circuitry, an additional routing layer can be formed on a side of the interposer opposite the HBM cubes 302. For example, the connective circuitry 408 can include TSVs that extend through the interposer, and routing circuitry can be formed thereat (e.g., after grinding to expose the TSVs) to provide connectivity to the connective circuitry opposite the HBM cubes 302. Similarly, the connective circuitry 406 can be formed in the routing layer opposite the HBM cubes 302.

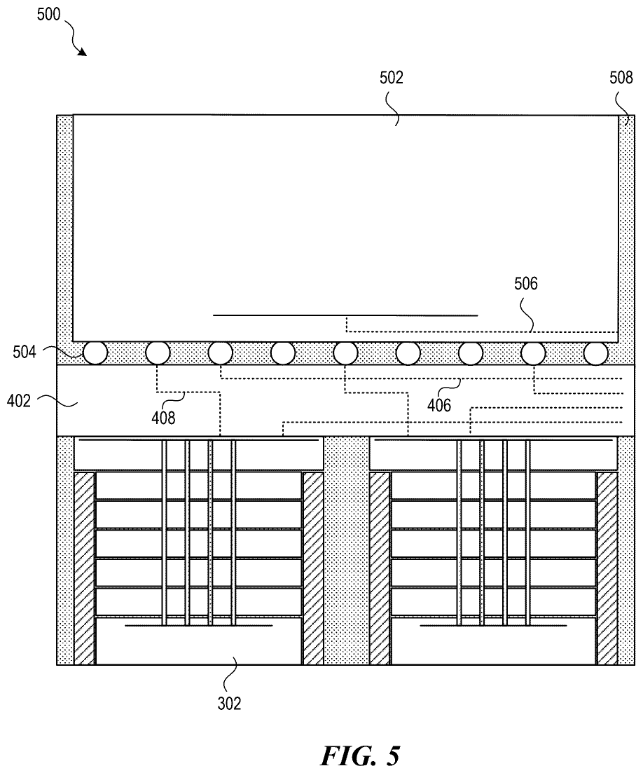

Once the routing layer of the redistribution layer 402 opposite the HBM cubes 302 is formed, host devices can be coupled to respective sets of the HBM cubes 302. For example, FIG. 5 illustrates a simplified schematic cross-sectional view of a semiconductor device assembly at stage 500, where a host device 502 is coupled with the redistribution layer 402. For example, the host device 502 is coupled with the redistribution layer 402 at the side opposite the HBM cubes 302 through connective structures 504 (e.g., solder balls, solder bumps, conductive pillars, or other conductive structures). The connective structures 504 couple with the connective circuitry 406 and the connective circuitry 408. In this way, the host device 502 couples with the HBM cubes 302 through the connective circuitry 408 and, once the connective circuitry 406 is exposed and connected, external connectivity is provided through the connective circuitry 406.

In some embodiments, additional connective circuitry 506 can be disposed at a routing layer of the host device 502 and extend out toward a periphery of the set of HBM cubes 302. In this way, the additional connective circuitry 506 can provide direct connectivity to the host device 502 exclusive of the redistribution layer 402 once exposed (e.g., through singulation or grinding). The routing layer can be formed from layers of dielectric material with selectively deposited conductive material used to implement routing circuitry.

In aspects, the host device 502 can be at least partially surrounded by a gap fill 508 (e.g., a mold resin or dielectric fill). For example, gaps between the host devices (e.g., similar to the host device 502) disposed across from the respective sets of the HBM cubes (e.g., similar to the HBM cubes 302) can be filled with the gap fill 508. In aspects, the gap fill 508 can be disposed up to a top surface of the host device 502, or the gap fill 508 can be thinned to expose the host device 502, to enable thermal contact therewith.

Although illustrated as forming the redistribution layer 402 at a reconstructed wafer formed from the HBM cubes 302 and then coupling the host device 502 to the redistribution layer 402, the redistribution layer 402 can instead be formed on a reconstructed wafer formed from the host device 502 and the HBM cubes 302 can be later attached. In this way, in some embodiments, the HBM cubes 302 can be coupled with the redistribution layer 402 before the host device 502, while in others, the host device 502 can be coupled with the redistribution layer 402 before coupling the HBM cubes 302 with the redistribution layer 402.

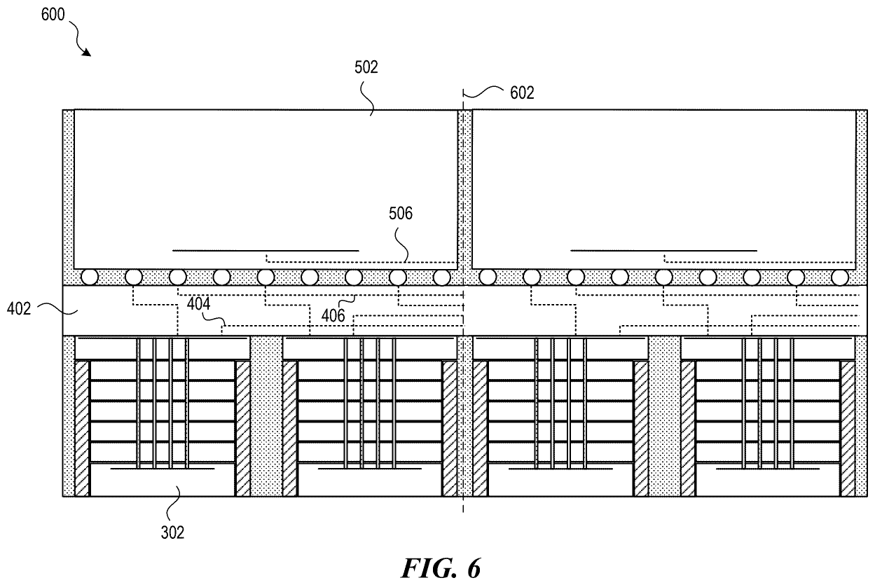

FIG. 6 illustrates a simplified schematic cross-sectional view of a semiconductor device assembly at stage 600, where the host device 502 and HBM cubes 302 are singulated. For example, sawing can be performed between the host devices and the sets of HBM cubes at streets 602. The sawing can cut through the redistribution layer 402 to expose the connective circuitry 404 and the connective circuitry 406. In some cases, the sawing alone exposes the connective circuitry 404 and the connective circuitry 406. In other cases, the redistribution layer 402 can be grinded to expose the connective circuitry 404 and the connective circuitry 406. The connective circuitry 506 can similarly be exposed through sawing or grinding.

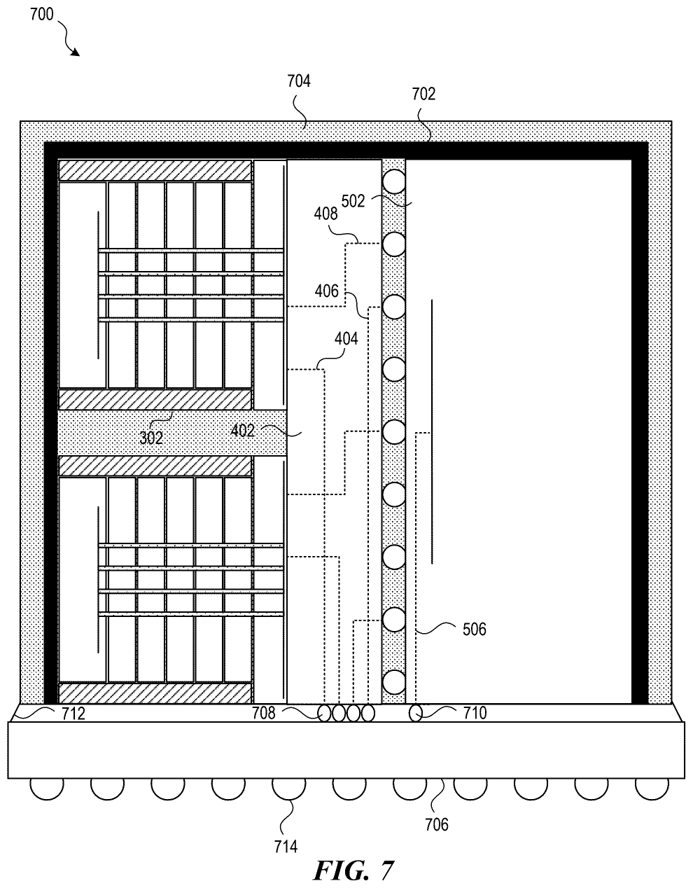

FIG. 7 illustrates a simplified schematic cross-sectional view of stage 700, where TIM 702 and a thermally conductive lid 704 are added to the singulated device and the singulated device is coupled to a substrate 706. The thermally conductive lid 704 can be disposed at least partially over the host device 502, the HBM cubes 302, and the redistribution layer 402. The thermally conductive lid 704 can extend vertically and horizontally to contact top and side surfaces of the host device 502 and the HBM cubes 302. The thermally conductive lid 704 can be disposed directly on a surface of the host device 502, the HBM cubes 302, or the redistribution layer 402 or proximate (e.g., within 1, 2, 5, 10, 100, or 500 microns) but spaced from the host device 502, the HBM cubes 302, or the redistribution layer 402 (e.g., by an encapsulant or the TIM 702). In general, however, the thermally conductive lid 704 can be thermally coupled with the host device 502 and the HBM cubes 302 to remove heat from the assembly. In aspects, the thermally conductive lid 704 can include any thermally conductive material such as aluminum, tin, copper, gold, or any other material having beneficial thermal properties (e.g., high thermal conductivity).

The TIM 702 can be used to dissipate heat from the HBM cubes 302, the redistribution layer 402, or the host device 502 through the thermally conductive lid 704. The TIM 702 can be disposed between the thermally conductive lid 704 and the host device 502, the HBM cubes 302, and the redistribution layer 402 to facilitate heat transfer between the components. For example, the TIM 702 can be disposed (e.g., dispensed, applied, deposited, and so on) over the tops of the host device 502 and the HBM cubes 302 or over one or more edge surfaces of the host device 502, the HBM cubes 302, or the redistribution layer 402. The TIM 702 can be disposed directly on a surface of the host device 502, the HBM cubes 302, or the redistribution layer 402 or proximate (e.g., within 1, 2, 5, 10, or 100 microns) but spaced from the host device 502, the HBM cubes 302, or the redistribution layer 402 (e.g., by an encapsulant or other material). The TIM 702 can be a thermal paste or grease, a thermal pad, phase change materials, or thermal adhesives. The TIM 702 can include a thermally conductive material. For example, the TIM 702 can include aluminum oxide, zinc oxide, boron nitride, polymers filled with thermally conductive material (e.g., ceramic powders or metal particles), or adhesives (e.g., epoxies) filled with thermally conductive materials (e.g., silver, aluminum, or ceramic).

The redistribution layer 402 can be coupled to the substrate 706 through connective structures 708 (e.g., solder bumps, solder balls, conductive pillars, or other conductive structures). For example, connective structures 708 can be coupled with the connective circuitry 404 and the connective circuitry 406 exposed at the edge of the redistribution layer 402. In aspects, the connective structures 708 can make contact with the connective circuitry 404 and the connective circuitry 406 directly at route lines or traces without requiring contact pads at the edge surface of the redistribution layer 402. In cases in which the host device 502 includes connective circuitry 506 exposed at the edge of the host device 502, connective structures 710 can similarly be coupled with the connective circuitry 506.

The substrate 706 can similarly include contacts (not shown) at an upper surface. The connective structures 708 can implement interconnects that electrically couple the host device 502 and the HBM cubes 302 with the substrate 706 (e.g., through the redistribution layer 402). The connective structures 708 can similarly implement interconnects between the host device 502 and the substrate 706 exclusive of the redistribution layer 402. An underfill material 712 (e.g., capillary underfill) can be disposed between the host device 502, the HBM cubes 302, and the redistribution layer 402 and the substrate 706 at least partially surrounding the connective structures 708 and the connective structures 710. The substrate 706 can include various circuitry (e.g., traces, lines, vias, or other connection structures) between the contacts at the upper surface and contacts (not shown) at a lower side of the substrate 706 at which connective structures 714 (e.g., solder balls) are disposed. In this way, external connectivity (e.g., power, ground, I/O, or other signaling) can be provided through the connective structures 714.

Although in the foregoing example embodiment, semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with more or fewer HBM cubes, more or fewer host devices, more or fewer dies within the HBM cubes or host device, or more or fewer interposers/redistribution layers, mutatis mutandis.

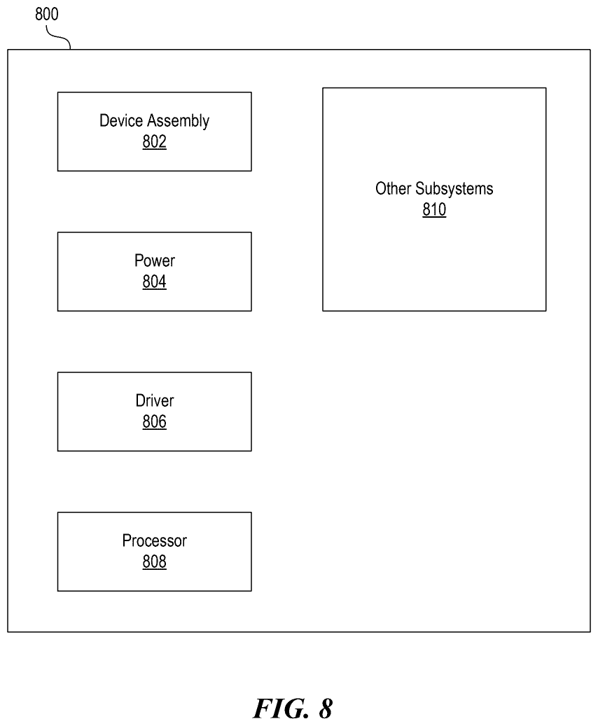

Any one of the semiconductor devices and semiconductor device assemblies described above with reference to FIGS. 1-7 can be incorporated into any of a myriad of larger and/or more complex systems, a representative example of which is system 800 shown schematically in FIG. 8. The system 800 can include a semiconductor device assembly 802 (e.g., a discrete semiconductor device), a power source 804, a driver 806, a processor 808, and/or other subsystems or components 810. The semiconductor device assembly 802 can include features generally similar to those of the semiconductor device assemblies described above with reference to FIGS. 1-7. The resulting system 800 can perform any of a wide variety of functions, such as memory storage, data processing, and/or other suitable functions. Accordingly, representative systems 800 can include, without limitation, handheld devices (e.g., mobile phones, tablets, digital readers, and digital audio players), computers, vehicles, appliances, and other products. Components of the system 800 may be housed in a single unit or distributed over multiple, interconnected units (e.g., through a communications network). The components of the system 800 can also include remote devices and any of a wide variety of computer-readable media.

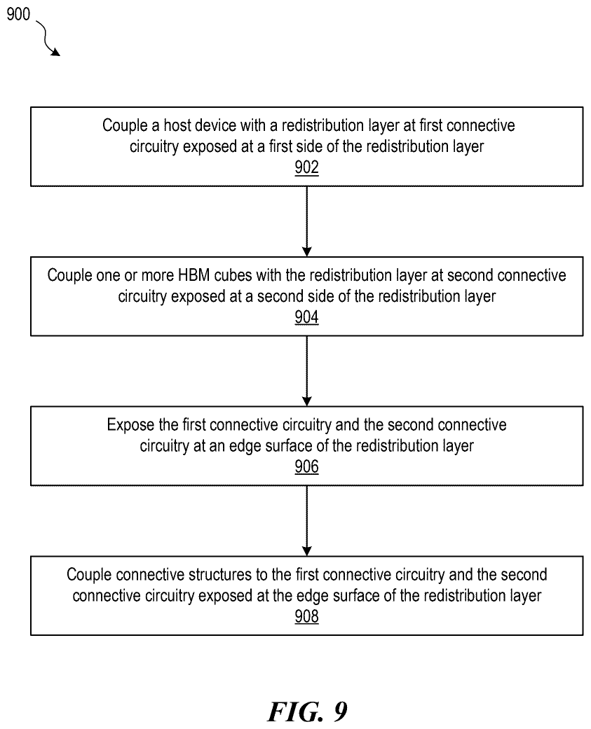

FIG. 9 illustrates an example method 900 for fabricating a semiconductor device assembly in accordance with an embodiment of the present technology. Although illustrated in a particular configuration, one or more operations of the method 900 may be omitted, repeated, or reorganized. Additionally, the method 900 may include other operations not illustrated in FIG. 9, for example, operations detailed in one or more other methods described herein.

At 902, a host device is coupled with a redistribution layer at first connective circuitry exposed at a first side of the redistribution layer. In aspects, the host device is a GPU, CPU, TCU, or other processing unit. The host device can be coupled with the redistribution layer in a face-down configuration. The redistribution layer can be implemented on a discrete interposer or formed directly on the host device. The first connective circuitry can be exposed at the first side to enable contact with the host device and extend out toward a periphery of the redistribution layer to enable the connective circuitry to be exposed at an edge of the redistribution layer.

At 904, one or more HBM cubes are coupled with the redistribution layer at second connective circuitry exposed at a second side of the redistribution layer opposite the first side. The second connective circuitry can be exposed at the first side to enable contact with the HBM cubes and extend out toward a periphery of the redistribution layer to enable the connective circuitry to be exposed at the edge of the redistribution layer. The HBM cubes can be coupled with the redistribution layer in a face-down configuration.

At 906, the first connective circuitry and the second connective circuitry are exposed at an edge surface of the redistribution layer. For example, the assembly can be sawed between a respective host device and sets of HBM cubes to singulate individual devices. This sawing can saw through the first connective circuitry or the second connective circuitry to expose this circuitry. In some embodiments, the side of the redistribution layer can be grinded (e.g., after singulation) to expose the first connective circuitry or the second connective circuitry.

At 908, connective structures are coupled to the first connective circuitry and the second connective circuitry exposed at the edge surface of the redistribution layer. The connective structures can be used to couple the host device and the HBM cubes to a package-level substrate through the redistribution layer. In doing so, a laid-down SiP can be assembled.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, plating, electroless plating, spin coating, and/or other suitable techniques. Similarly, materials can be removed, for example, using plasma etching, wet etching, chemical mechanical planarization (CMP), or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or 3Di applications.

The devices discussed herein, including memory devices, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A system-in-package (SiP) device, comprising:
an interposer comprising a first side, a second side opposite the first side, and an edge surface extending between the first side and the second side;
a first semiconductor device coupled to the first side of the interposer;
a stack of second semiconductor devices coupled to the second side of the interposer;
first connective circuitry extending through the interposer, coupled with the first semiconductor device, and exposed at the edge surface of the interposer;
second connective circuitry extending through the interposer, coupled with the stack of second semiconductor devices, and exposed at the edge surface of the interposer; and
one or more connective structures coupled with the first connective circuitry and the second connective circuitry exposed at the edge surface of the interposer.

2. The SiP device of claim 1, wherein the first semiconductor device comprises a host device and the second semiconductor devices comprise memory devices.

3. The SiP device of claim 1, further comprising third connective circuitry extending between the first side and the second side of the interposer and coupling the first semiconductor device and the stack of second semiconductor devices.

4. The SiP device of claim 3, wherein the third connective circuitry comprises through-substrate vias (TSVs).

5. The SiP device of claim 1, further comprising:
a routing layer disposed at the first semiconductor device between the interposer and the first semiconductor device, the routing layer having an edge surface substantially coplanar with the edge surface of the interposer;
third connective circuitry extending through the routing layer of the first semiconductor device, coupled with the first semiconductor device, and exposed at the edge surface of the routing layer; and
one or more additional connective structures coupled with the third connective circuitry exposed at the edge surface of the routing layer.

6. The SiP device of claim 1, wherein a front side of the first semiconductor device faces a front side of the stack of second semiconductor devices.

7. The SiP device of claim 1, further comprising a conductive lid thermally interfacing with the first semiconductor device and the stack of second semiconductor devices.

8. The SiP device of claim 7, further comprising a thermal interface material disposed between the conductive lid and at least a portion of the first semiconductor device, the stack of second semiconductor devices, and the interposer.

9. A semiconductor device, comprising:
a host device;
one or more memory stack cubes;
a redistribution layer disposed between and coupling the host device and the one or more memory stack cubes, the redistribution layer having an edge surface extending between the host device and the one or more memory stack cubes;
first connective circuitry extending through the redistribution layer, coupled with the host device, and exposed at the edge surface of the redistribution layer;
second connective circuitry extending through the redistribution layer, coupled with the one or more memory stack cubes, and exposed at the edge surface of the redistribution layer; and
connective structures coupled with the first connective circuitry and the second connective circuitry exposed at the edge surface of the redistribution layer.

10. The semiconductor device of claim 9, wherein the one or more memory stack cubes comprise one or more high-bandwidth memory (HBM) cubes.

11. The semiconductor device of claim 9, further comprising third connective circuitry extending through the redistribution layer and coupling the host device and the one or more memory stack cubes.

12. The semiconductor device of claim 9, wherein the redistribution layer is formed on the host device or the one or more memory stack cubes.

13. The semiconductor device of claim 9, further comprising a conductive lid thermally interfacing with the host device and the one or more memory stack cubes.

14. A method comprising:
coupling a host device with a redistribution layer at first connective circuitry exposed at a first side of the redistribution layer;
coupling one or more memory stack cubes with the redistribution layer at second connective circuitry exposed at a second side of the redistribution layer opposite the first side;
exposing the first connective circuitry and the second connective circuitry at an edge surface of the redistribution layer extending between the first side and the second side; and
coupling connective structures to the first connective circuitry and the second connective circuitry exposed at the edge surface of the redistribution layer.

15. The method of claim 14, further comprising grinding the edge surface of the redistribution layer to expose the first connective circuitry and the second connective circuitry at the edge surface of the redistribution layer.

16. The method of claim 14, further comprising:
coupling the host device and the redistribution layer at third connective circuitry exposed at the first side of the redistribution layer, the third connective circuitry extending through the redistribution layer and exposed at the second side of the redistribution layer; and
coupling the one or more memory stack cubes with the redistribution layer at the third connective circuitry exposed at the second side of the redistribution layer.

17. The method of claim 14, further comprising:
disposing a routing layer at and coupled with the host device, the routing layer comprising third connective circuitry exposed at an edge surface of the routing layer; and
disposing one or more additional connective structures at the third connective circuitry exposed at the edge surface of the routing layer.

18. The method of claim 14, further comprising coupling the host device and the one or more memory stack cubes with the redistribution layer such that a front side of the host device faces front sides of the one or more memory stack cubes.

19. The method of claim 14, further comprising disposing a conductive lid at least partially over the host device and the one or more memory stack cubes.

20. The method of claim 14, further comprising:
disposing a thermal interface material disposed over at least a portion of the host device, the one or more memory stack cubes, and the redistribution layer; and
disposing a thermally conductive lid at least partially over the thermal interface material.
